(19) United States
(12) Patent Application Publication
(10) Pub. No.: US 2016/0035923 A1
(43) Pub. Date: Feb. 4, 2016

(54) COVER GLASS FOR SOLAR CELL, SOLAR CELL MODULE PROVIDED WITH COVER GLASS FOR SOLAR CELL, COATING LIQUID FOR FORMING TRANSPARENT FILM, AND METHOD FOR FORMING TRANSPARENT PROTECTIVE FILM

(71) Applicant: FUTURE EVE TECHNOLOGY Co, Ltd, Kumamoto (JP)

(72) Inventor: Isao OKAMURA, Kumamoto (JP)

(21) Appl. No.: 14/882,831

(22) Filed: Oct. 14, 2015

Related U.S. Application Data
(63) Continuation of application No. PCT/JP2014/060686, filed on Apr. 15, 2014.

(30) Foreign Application Priority Data
Apr. 15, 2013 (JP) 2013-085123

(51) Int. Cl. H01L 31/055; C03C 17/10; C01B 19/00; H01L 31/0216; H01L 31/18

(52) U.S. Cl. CPC H01L 31/055; H01L 31/02167; H01L 31/18; C01B 19/007; C03C 17/10

(57) ABSTRACT

A provided cover glass for a solar cell panel has excellent transparency, and minimal incidence so-called “glass surface turbidity” due to reactions with components contained in a glass substrate. The cover glass for the solar cell panel comprises: the glass substrate including a surface; and a transparent protective film containing zinc telluride for coating the surface. Particularly, in the cover glass for the solar cell panel, the transparent protective film is preferably formed by bonding the zinc telluride with silica binders. Such a transparent protective film has excellent transparency, and reactions of the contained zinc telluride inhibit the surface of the glass substrate, which is a base of the solar cell, from becoming turbid.

### CROSS-REFERENCE TO RELATED APPLICATIONS

This application is a continuation application of International Patent Application No. PCT/JP2014/060686 filed on Apr. 15, 2014, which claims priority to Japanese Patent Application No. 2013-085123 filed on Apr. 15, 2013 in Japan, the entire contents of which are incorporated by reference in their entirety herein.

### BACKGROUND OF THE INVENTION

1. Field of the Invention

The present invention relates to: cover glass for a solar cell whose surface is coated with a transparent protective film; a solar cell module provided there-with; coating liquid for forming the film; and a method for forming the film.

2. Description of the Related Art

A solar cell module normally adapts a structure that a solar cell is arranged between a back sheet and a cover glass, and that the arranged elements are sealed with resin sealing material. FIG. 1 shows an example of a module used for a general solar power-generating system. As shown in FIG. 1, the solar cell module is used outdoors in general. A cover glass for a solar cell, which may be simply called as a “cover glass” hereinafter, is utilized as a member for protecting power-generating elements, which contain inner silicone or the like.

In order to improve conversion efficiency of the solar cell, the cell should take more amount of sunlight therein. Accordingly, the cover glass must have excellent transparency and low reflectivity. Characteristics required of the cover glass for the solar cell are not only optical characteristic (e.g. the transparency) but also weather-ability (e.g. UV resistance, wet resistance, heat resistance, or the like), mechanical characteristic (e.g. tensile strength, elongation, tear strength, or the like), and properties when integrating with resin sealing material by adhering, and so on.

Lifetime of the cover glass for the solar cell is an important factor that determines lifetime of the solar cell module itself. The cover glass of the solar cell may be deteriorated according to the following repeated reactions. The cover glass is always exposed to the weather. Yellow sand, ash, dust, dirt or the like may be adhered thereon, and oxidation and/or carbonization by resolution caused thereby may repeatedly occur.

If the surface of the cover glass gets wet and dry over and over again, components, which derive from sodium or the like of alkali metal and calcium or the like of alkaline earth metal, are eluted from the glass, and the eluted components and sour gas (e.g. carbon dioxide and/or sulfurous acid gas in the air) react with each other, and the surface of the glass becomes milky, that is, so-called “glass surface turbidity” occurs. Once the “glass surface turbidity” occurs, the conversion efficiency of the solar cell module remarkably falls since the transparency of the cover glass is reduced.

In order to suppress the reduction of the efficiency caused by light reflection on the cover glass for the solar cell, cover glass whose surface is coated with a low reflective film so as to improve light collection efficiency has been proposed. For example, Reference 2 (Japanese patent application Laid-open on No. 2010-199143) discloses cover glass whose surface is coated with a fluorine-resin layer. Reference 3 (Japanese patent application Laid-open on No. 2004-292194) discloses cover glass for a solar cell as configured according to the steps of:

(1) applying process liquid to a surface of a transparent glass substrate, the process liquid containing: organic silicon compounds (A); binder resin (B) which is thermally decomposed at 40-270 Centigrade degrees; and organic solvent (C);
(2) drying the applied process liquid; and
(3) flying the glass substrate with the applied layer at 400-800 Centigrade degrees so that the fried applied layer has a porosity of 15-25%.

Reference 4 (Japanese patent application Laid-open on No. 2008-260654) discloses cover glass for a solar cell coated with a low reflective film containing silicon oxide (SiO₂) and niobium oxide (Nb₂O₅) formed by a sputtering method.

### LIST OF CITED REFERENCES

[Reference 1]: Japanese patent application Laid-open on No. 2001-358346

[Reference 2]: Japanese patent application Laid-open on No. 2010-199143

[Reference 3]: Japanese patent application Laid-open on No. 2004-292194

[Reference 4]: Japanese patent application Laid-open on No. 2008-260654

The cover glass disclosed in Reference 2, however, includes a coating layer of organic resin. There is a durability problem when it has been used outdoors for a long time. The cover glass disclosed in Reference 3 requires high temperature over 400 Centigrade degrees so as to densify a coating layer formed on a surface thereof. Accordingly, transparency may be reduced caused by thermal deterioration of the glass substrate, and/or reactions between the glass substrate and the coating layer may draw trouble. Niobium oxide is used in the cover glass disclosed in Reference 4, and is a suitable component for forming the low reflective film since its transmission wavelength has a range from visible light (near-ultraviolet) to infrared light. Its alkali resistance, however, is low, and it may react with sodium, calcium, or the like contained in the glass substrate. Since Reference 4 assumes that a film-forming method according to a sputtering method is used, expensive devices such as vacuum equipment are needed. There is another problem that the cost must be remarkably higher.

The conventional cover glass cannot solve the problem of “glass surface turbidity” that occurs when the glass is always exposed to water and used.

In order to inhibit the problem of “glass surface turbidity”, (sodium-free and calcium-free) glass not containing source elements of alkali metal and alkaline earth metal may be used for the cover glass. Such glass, however, is very expensive, and the cost of the whole solar cell module must be remarkably higher. For the substrate of the cover glass, a transparent plastic (for example, polycarbonate (PC), polymethyl methacrylate (PMMA), or the like) substrate may be used instead of the glass substrate. It is difficult to ensure stability corresponding to lifetime of the solar cell module.

### OBJECTS AND SUMMARY OF THE INVENTION

In view of the above, an object according to the present invention is to provide: cover glass for a solar cell panel whose transparent protective film that has excellent transparency and that so-called “glass surface turbidity” caused by components contained in a glass substrate hardly occurs even if it has been used for a long time; and a solar cell module equipped with the same.

Another object according to the present invention is to provide: coating liquid for forming the transparent protective film; and a method for forming the same.

The inventor has been eagerly studied resolution for the above problems, and finally has found the fact that coating the glass substrate with a transparent protective film containing zinc telluride enables to inhibit so-called “glass surface turbidity” even if a cheap glass substrate containing sodium of alkali metal and calcium of alkaline earth metal or the like is used. That is, the inventor has achieved the present invention.

The present invention relates to the following aspects.

A first aspect of the present invention provides cover glass for a solar cell, the cover glass comprising: a glass substrate including a surface; and a transparent protective film containing zinc telluride for coating the surface.

A second aspect of the present invention provides, in addition to the first aspect, wherein the transparent protective film is formed by bonding the zinc telluride with silica binders.

A third aspect according to the present invention provides, in addition to any of the first and the second aspects, wherein the transparent protective film contains titanium oxide.

A fourth aspect according to the present invention provides, in addition to any of the first to the third aspects, wherein the transparent protective film has thickness of 20-1200 nanometers.

A fifth aspect according to the present invention provides, in addition to any of the first to the fourth aspects, wherein the glass substrate contains elements belonging to at least one of alkali metal and alkaline earth metal.

A sixth aspect according to the present invention provides a solar cell module, including the cover glass as defined in any of the first to the fifth aspects.

A seventh aspect according to the present invention provides coating liquid for forming a transparent protective film, containing zinc telluride, wherein a pH of the coating liquid is not less than nine.

An eighth aspect of the invention provides, in addition to the seventh aspect, the coating liquid containing the zinc telluride of 0.1-20 wt % based on total 100 wt % of the coating liquid.

A ninth aspect according to the present invention provides, in addition to any of the seventh and the eighth aspects, the coating liquid further containing silica binders of 0.1-20 wt % in terms of SiO₂ based on the total 100 wt % of the coating liquid.

A tenth aspect according to the present invention provides, in addition to any of the seventh to the ninth aspects, the coating liquid further containing titanium oxide of 0.1-20 wt % based on the total 100 wt % of the coating liquid.

An eleventh aspect according to the present invention provides, in addition to any of the seventh to the tenth aspects, the coating liquid further containing: iodine of 0.1-10 wt %; and silver compounds of 0.1-10 wt % based on the total 100 wt % of the coating liquid.

A twelfth aspect according to the present invention provides, in addition to any of the seventh to eleventh aspects, wherein mixed solvents containing ethanol of 20-40 wt % and water of 40-80 wt % are used.

A thirteenth aspect according to the present invention provides a method for forming a transparent protective film, comprising: coating the coating liquid as defined in any of the seventh to the twelfth aspects on a surface of a glass substrate; and curing the coated coating liquid.

The present invention provides cover glass for a solar cell, the cover glass being coated by the transparent protective film that inhibits deterioration of the glass substrate and that modulates irradiated outside light into a visible light band. According to the solar module provided with the cover glass for the solar cell, power-generating efficiency is improved and lifetime becomes longer since the deterioration of the cover glass is inhibited.

### BRIEF DESCRIPTION OF THE DRAWINGS

FIG. 1 is a cross-section mimetic diagram of a solar cell module; and

FIG. 2 is a cross-section mimetic diagram of cover glass for a solar cell according to the present invention.

### DETAILED DESCRIPTION OF THE PREFERRED EMBODIMENTS

Hereinafter, the present invention will now be described in detail showing examples thereof. The present invention is never limited to the examples. Arbitrary change from the examples may be carried out within the scope and/or the aspects of the present invention.

### [1. Cover Glass for Solar Cell]

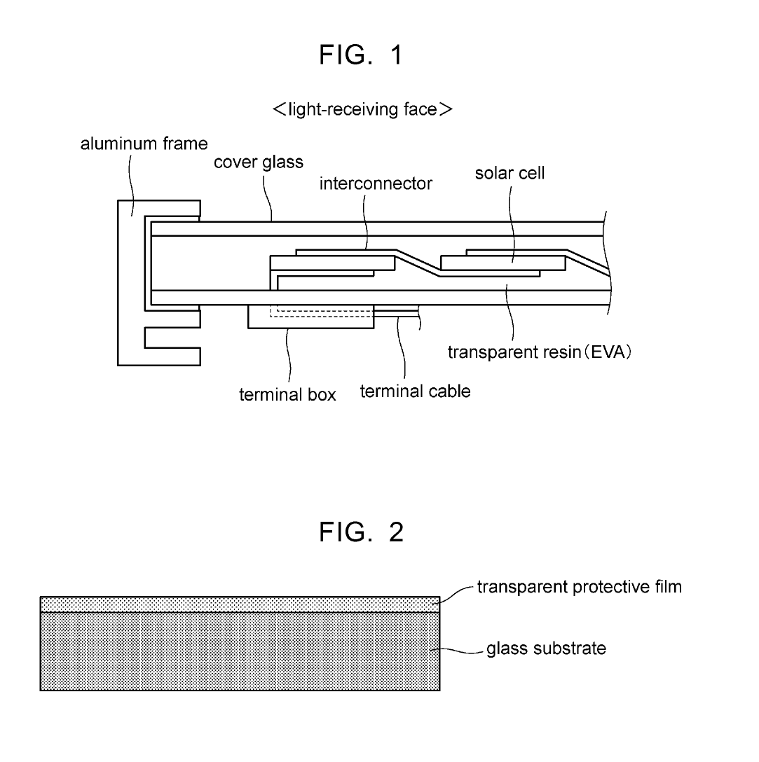

Cover glass for a solar cell according to the present invention is provided with: a glass substrate including a surface; and a transparent protective film containing zinc telluride, the transparent protective film coating the surface. That is, the surface of the glass substrate of the cover glass for the solar cell according to the present invention is coated by the transparent protective film containing the zinc telluride. As shown in FIG. 1, the cover glass for the solar cell is a protection member protecting the solar cell in a solar cell module. As shown in FIG. 2, the cover glass for the solar cell according to the present invention (hereinafter, may by called “the cover glass according to the present invention”) possesses a structure that the surface of the glass substrate is coated by the transparent protective film. In FIG. 2, the transparent protective film is formed only on an upper surface of the glass substrate. Alternatively, the transparent protective film may be formed on both of the upper surface and a lower surface of the glass substrate. Hereafter, details of the cover glass according to the present invention will now be explained.

### (Glass Substrate)

A generally used glass substrate can be employed as cover glass for a solar cell. Such a glass substrate has transmittance for transmitting sun light. More concretely, soda-lime silicate glass, alumino-silicate glass, barium borosilicate glass, borosilicate glass, or the like is suitable for constituting the glass substrate. These kinds of glass may contain at least one of potassium (K), and sodium (Na), or the like belonging to alkali metal and calcium (Ca), Magnesium (Mg), or the like belonging to alkaline earth metal within a range contained in process for producing it. Glass for constituting the glass substrate may be functional glass, such as colored glass and laminated glass.

Glass substantially containing neither alkali metal element nor alkaline earth metal element may be employed as the glass substrate. Since a transparent protective film, details of which will be discussed later, exists in the cover glass according to the present invention, so-called “glass surface turbidity” caused by reactions between acid gas (e.g. CO2 in the air, or the like) and at least one of alkali metal elements and alkaline earth metal elements is inhibited. Even if the glass substrate contains at least one of alkali metal elements and alkaline earth metal elements, deterioration, especially caused by so-called “glass surface turbidity”, hardly occurs. For this reason, the glass substrate contains at least one of alkali metal elements and alkaline earth metal elements may be suitably employed as the cover glass according to the present invention.

Thickness of the glass substrate is determined considering mechanical strength needed as the cover glass and transmittance of sun light. Size (area) of the glass substrate is determined corresponding to that of a target solar cell module.

### (Transparent Protective Film)

In the cover glass according to the present invention, a transparent protective film (hereinafter, may be called “the transparent protective film according to the present invention”) contains zinc telluride (ZnTe) as an essential constituent, and coats the glass substrate. The transparent protective film according to the present invention has excellent transparency of sun light, and can inhibit deterioration (especially, so-called “glass surface turbidity”) of the glass substrate. In a case where zinc telluride is not contained therein, effects of the inhibition cannot be recognized.

Containing zinc telluride enables to modulate ultraviolet light included in irradiated sun light into visible light of a band near 600 nanometers, thereby improving power-generating efficiency.

At this time, it is not completely clear why forming the transparent protective film according to the present invention enables to inhibit so-called “glass surface turbidity.” It is supposed, however, that zinc telluride of conductive oxide acts on free electrons in the glass of an insulator to restrain reactions between acid gas (e.g. CO₂) and at least one of alkali metal (e.g. sodium, calcium, or the like) and alkaline earth metal contained in the glass, thereby inhibiting so-called “glass surface turbidity” caused by the reactions.

Particle size of zinc telluride is determined in a range of 0.1-500 micrometers, in which effects of the present invention can be obtained.

The transparent protective film according to the present invention is preferably formed by bonding zinc telluride with silica binders. The transparent protective film according to the present invention may be formed only with zinc telluride. Binders are usually contained therein so as to increase mechanical strength. As the binders, those with excellent transparency are selected, and both of inorganic binders and organic binders can be chosen. Particularly, silica binders, which have excellent transparency, high light resistance, and enough mechanical strength, are preferably used for the binders.

The ratio between the zinc telluride and the silica binders in the transparent protective film is determined within a range where effects of the present invention are not spoiled. Normally, the silica binders have 10-50 wt % in terms of SiO₂ based on weight 100% of the zinc telluride.

Since the cover glass according to the present invention is provided with the transparent protective film, heat reflection effects are also expected. Due to the effects, it is possible to prevent the temperature of the panel from rising too high. Accordingly, loss of power-generating efficiency caused by overheating of the solar cell module is also controlled.

The transparent protective film according to the present invention preferably further contains titanium oxide. As the titanium oxide, both of an anatase crystal type and a rutile crystal type can be used. Yellow sand, ash, dust, dirt or the like may be adhered on the surface of the cover glass for a solar cell, which is normally used outdoors, to form attachment. Therefore, transmittance of sun light is reduced, and chemical reactions, such as oxidation of the attachment and/or carbonization by resolution may cause deterioration of the glass. When the transparent protective film according to the present invention contains titanium oxide, the attachment can be removed due to photocatalyst effect of the contained titanium oxide, thereby restraining the reduction of transmittance of sun light and the deterioration of the glass. In this specification, the photocatalyst effect includes the titanium oxide's function of making something into a super-hydrophilic state. The attachment on the surface can be easily removed by washing with water (including rain water) according to the function. The titanium oxide modulates ultraviolet into a visible light band. Containing the titanium oxide in the transparent protective film according to the present invention enables to improve power-generating efficiency thereof.

A ratio of the titanium oxide in the transparent protective film may be determined in a range where the transparent protective film performs the photocatalyst effect. If the ratio of the contained titanium oxide is too large, strength of the transparent protective film may be not enough and the above effect caused by zinc telluride may become weak. The ratio is normally 1-40 wt % based on the total weight 100% of the transparent protective film.

As long as not spoiling the effects of the present invention, the transparent protective film may further contain another kind of well-known wavelength conversion material so as to modulate ultraviolet into the visible light band.

The transparent protective film according to the present invention preferably contains silver ions (Ag+). The silver ions can reinforce action of visible light.

As long as not spoiling the effects of the present invention of restraining so-called “glass surface turbidity”, the thickness of the transparent protective film is not limited. The thickness is preferably, however, 20-1200 nanometers so as to make the wavelength conversion function effective. Herein, the thickness of the transparent protective film can be measured utilizing a film thickness-measuring instrument (e.g. “F20 system” of Filmetrics, Inc.).

### [2. Method for Forming Transparent Protective Film]

As long as not spoiling the above-mentioned act, the transparent protective film according to the present invention may be formed according to any method, such as a dry film-forming method (e.g. a vapor deposition method, a spattering method, or the like), a wet film-forming method of coating liquid on a surface to form the film. Herein, the dry film-forming method needs expensive equipment, such as vacuum equipment. The wet film-forming method is preferable, since the film can be produced by low cost.

### (Coating Liquid for Transparent Protective Film)

Coating liquid (hereinafter simply called “coating liquid according to the present invention” or merely called “coating liquid”) suitable for the transparent protective film according to the present invention will now be explained. The coating liquid assumes the wet film-forming method.

The coating liquid for the transparent protective film according to the present invention contains zinc telluride, and a pH thereof is not less than nine. The contained zinc telluride in the coating liquid preferably has 0.1-20 wt % based on total 100 wt % of the coating liquid.

Such composition provides excellent applicability on a surface of a glass substrate, and one time application thereof enables to form a uniform transparent protective film on the surface of the glass substrate. Two or more times application may be performed in order to make the transparent protective film thicker.

Solvent of the coating liquid according to the present invention is aqueous solvent having a pH not less than nine. Herein, the aqueous solvent means not less than 40 wt % based on total weight of the solvent is composed of water. If a pH of the solvent of the coating liquid is smaller than nine, applicability of the coating liquid falls and a uniform film cannot be formed. The solvent of the coating liquid is preferably mixed solvent containing ethanol of 20-40 wt % and water of 40-80 wt % in order to improve the applicability of the coating liquid, thereby forming a film of high quality.

The coating liquid preferably contains binder components. Containing the binder components enables to reinforce strength of the formed transparent protective film, and to improve adhesiveness with the glass substrate. Both of inorganic binders with high transparency and organic binders may be selected for the binders. Silica binders are preferably employed, since the silica binders have excellent transparency, high light resistance, and enough mechanical strength. The preferable ratio of the silica binders is 0.1-20 wt % in terms of SiO₂ based the total weight 100 wt % of the coating liquid.

In addition to the above components (the zinc telluride, the binders, and the solvent), the coating liquid according to the present invention preferably further contains titanium oxide of 0.1-20 wt % based on the total 100 wt % of the coating liquid so as to improve wavelength conversion properties of the formed transparent protective film and to add photocatalyst effects to the same.

The coating liquid according to the present invention preferably further contains iodine of 0.1-10 wt % and silver compounds of 0.1-10 wt %, since effects of further improving the wavelength conversion properties are expected. An as long as capable of ionizing, any kinds of silver compounds may be employed. Silver chloride (AgCl) can be given as a preferable example.

Components other than the above-mentioned components may be mixed into the coating liquid according to the present invention as long as not spoiling the effects of the present invention. Components for improving characteristics of the coating liquid such as surfactant or the like can be given as an example of the components to be mixed.

The coating liquid according to the present invention can be manufactured by mixing components constituting thereof. Mixing order is arbitrary. For example, first, prior to the other necessary components, two or three components may be mixed, and second, the remainder of the necessary components may be further mixed thereto. Alternatively, all of the necessary components may be mixed at once.

The transparent protective film according to the present invention can be suitably manufactured by:

applying the coating liquid according to the present invention on a surface of the glass substrate; and
curing the applied coating liquid.

Details of the glass substrate, which is a target to be applied, are as above-discussed.

There is no special limitation with respect to a method for applying the coating liquid on the surface of the glass substrate. Any of well-known wet film-forming methods can be adapted for the method. More concretely, a spin coat method, a slit die-coating method, a spray coat method, a dip-coating method, a roll-coating method, a screen printing method, a capillary coat method, a bar coater method, or the like are given as the well-known methods. Thickness of the coating liquid is controllable by respectively adjusting consistencies and amounts of the components contained in the coating liquid.

Curing the coating liquid applied on the surface of the glass substrate enables to preferably manufacture the transparent protective film according to the present invention. There is no limitation with respect to a method for curing the applied coating liquid as long as the formed transparent protective film has sufficient transparency and enough mechanical strength. The method is normally performed by heating the applied coating liquid. Heating atmosphere is not limited. However, air atmosphere is normally used.

Since the coating liquid according to the present invention can be cured by heating at relatively low temperature, suitable curing temperature is usually about 10-100 centigrade degrees. Curing time is time for the transparent protective film to fully harden, and is suitably determined considering composition of the coating liquid and thickness of the transparent protective film to be formed.

Thus, the glass substrate possessing a surface covered by the transparent protective film can be employed as the cover glass for a solar cell according to the present invention. The transparent protective film formed with the coating liquid according to the present invention can be also employed as a transparent protective film for glass for automobile, a lighting apparatus, a liquid crystal display, or the like other than the cover glass for the solar cell.

### [3. Solar Cell Module]

The solar cell module according to the present invention comprises the above-mentioned cover glass for the solar cell. Elements other than the cover glass are not limited but the same elements as well-known solar cell modules can be used. FIG. 1 is an example of a structure of the solar cell module. The solar cell module according to the present invention may include wired electrodes, extraction electrodes, or the like in addition to elements shown in FIG. 1.

Especially material of cell portions in the solar cell module is not limited. For example, silicone based material, such as single crystal silicon, polycrystalline silicon, and amorphous silicone, and CIS type compound semiconductor material including a light-absorbing layer of P-type semiconductor and a PN hetero junction may be given. Composition of the transparent protective film according to the present invention is determined considering absorption wave length of the material of the cell portions.

### EXAMPLES

Hereafter, details of the present invention will now be explained showing Examples. The present invention, however, is not limited to the following Examples as long as the scope of the present invention is not changed.

A used reagent and composition of a glass substrate are as follows:

### “Reagent”

Powder of zinc telluride (II) (made by Kojundo Chemical Laboratory Co., Ltd.)
Titanium oxide (IV) (rutile type) (made by Wako Pure Chemical Industries, Ltd.)

### “Glass Substrate”

### (Composition)

### SiO₂: 70-72 wt %;

### Na₂O: 13-15 wt %;

### CaO: 8-12 wt %;

### MgO: 1-4 wt %;

### Al₂O₃: 1-2 wt %; and

### Fe₂O₃: 0.07-0.15 wt %.

### Example 1

### (1) Manufacturing Coating Liquid

The coating liquid 1 concerning Example 1 was produced according to the following procedures. First, sodium hydroxide was added to pure water, and then the added water was prepared so as to have a pH of 12.5. Next, 2 g of zinc telluride powder was added to 370 milliliters of water prepared to have a pH of 12.5. The added water was fully mixed so as to become uniform, and then Solution A was obtained. 4 g of titanium-oxide powder was added to 390 milliliters of pure-water, and the added water was fully mixed so as to become uniform, and the Solution B was obtained. 1 g of silver chloride and 4 g of iodine was added to 270 milliliters of ethanol, and the added ethanol was fully mixed so as to become uniform, and then Solution C was obtained. The Solution A and the Solution B were respectively added to 275 milliliters of the Solution C, the Solution A, B and C was fully mixed so as to become uniform, and then coating liquid 1 was prepared. The composition of the obtained coating liquid 1 is as follows.

Zinc telluride: 0.2 wt %;
Titanium oxide: 0.4 wt %;
Silver chloride: 0.1 wt %;

### Ethanol: 35 wt %; and

### Water: 60 wt %.

### (2) Manufacturing Cover Glass for Solar Cell

Forming the transparent protective film on the glass substrate was performed according the following procedures. The coating liquid 1 was applied on a glass substrate (600×900 mm, thickness: 3 mm), and the applied coating liquid was dried. Thereby, cover glass for a solar cell of Example 1 whose surface of the glass substrate has been coated with the transparent protective film was obtained. The thickness of the transparent protective film measured with a film thickness-measuring instrument (“F20 system” of Filmetrics, Inc.) was 60 nanometers

### (3) Evaluation

The cover glass for the solar cell of Example 1 was arranged to coat a light-receiving face of a silicon solar cell, and power-generating efficiency was evaluated. A first result thereof was 107%. Herein, the power-generating efficiency is a relative value assuming that a clear glass substrate (comparative example) on which the transparent protective film is not formed has 100% of generation efficiency.

### Example 2

### (1) Manufacturing Coating Liquid 2

1000 g of coating liquid 1 and 2000 g of ceramic based resin was mixed to obtain Coating liquid 2. The ceramic based resin contains silica as binder components.

### (2) Manufacturing of Cover Glass for Solar Cell

Not Coating liquid 1 but Coating liquid 2 was used to obtain the cover glass for the solar cell of Example 2 whose surface of the glass substrate has been coated with the transparent protective film was obtained.

### (3) Evaluation

Similar to Example 1, except for using the cover glass for the solar cell of Example 2 instead of the cover glass for the solar cell of Example 1, power-generating efficiency was evaluated. A second result thereof was 107%.

### INDUSTRIAL APPLICABILITY

The present invention provides the cover glass for solar cell panels has excellent transparency, and minimal incidence so-called “glass surface turbidity” caused by reactions with components contained in a glass substrate. The cover glass is good at removing substances adhered on the surface, and can also prevent from rising temperature of the panel. Even if the cover glass has been used for a long time, it is possible to control decline of power-generating efficiency. The present invention has such advantage in industrial fields.

What is claimed is:

1. Cover glass for a solar cell, the cover glass comprising:
a glass substrate including a surface; and
a transparent protective film containing zinc telluride for coating the surface.

2. The cover glass as defined in claim 1, wherein said transparent protective film is formed by bonding the zinc telluride with silica binders.

3. The cover glass as defined in claim 1, wherein said transparent protective film contains titanium oxide.

4. The cover glass as defined in claim 1, wherein said transparent protective film has thickness of 20-1200 nanometers.

5. The cover glass as defined in claim 1, wherein said glass substrate contains elements belonging to at least one of alkali metal and alkaline earth metal.

6. A solar cell module, including the cover glass as defined in claim 1.

7. Coating liquid for forming a transparent protective film, containing zinc telluride, wherein a pH of the coating liquid is not less than nine.

8. The coating liquid as defined in claim 7, containing the zinc telluride of 0.1-20 wt % based on total 100 wt % of the coating liquid.

9. The coating liquid as defined in claim 7, further containing silica binders of 0.1-20 wt % in terms of SiO₂ based on the total 100 wt % of the coating liquid.

10. The coating liquid as defined in claim 7, further containing titanium oxide of 0.1-20 wt % based on the total 100 wt % of the coating liquid.

11. The coating liquid as defined in claim 7, further containing: iodine of 0.1-10 wt %; and silver compounds of 0.1-10 wt % based on the total 100 wt % of the coating liquid.

12. The coating liquid as defined in claim 7, wherein mixed solvent containing ethanol of 20-40 wt % and water of 40-80 wt % is used.

13. A method for forming a transparent protective film, comprising:
coating the coating liquid as defined in claim 7 on a surface of a glass substrate; and
curing the coated coating liquid.
